(19) United States
(12) Patent Application Publication
(10) Pub. No.: US 2025/0344322 A1
(43) Pub. Date: Nov. 6, 2025

(54) PRINTED CIRCUIT BOARD

(71) Applicant: SAMSUNG ELECTRO-MECHANICS CO., LTD., Suwon-si (KR)

(72) Inventor: Dae Jung BYUN, Suwon-si (KR)

(73) Assignee: SAMSUNG ELECTRO-MECHANICS CO., LTD., Suwon-si (KR)

(21) Appl. No.: 19/028,195

(22) Filed: Jan. 17, 2025

(30) Foreign Application Priority Data
May 2, 2024 (KR) 10-2024-0058241

(51) Int. Cl. H05K 1/18; H05K 1/03; H05K 1/11; H05K 3/00

(52) U.S. Cl. CPC H05K 1/185; H05K 1/0313; H05K 1/115; H05K 3/0047; H05K 2201/09481; H05K 2201/09609; H05K 2201/09618; H05K 2201/10015; H05K 2201/10515; H05K 2201/10522

(57) ABSTRACT

The present disclosure relates to a printed circuit board, the printed circuit board including: a component laminate including an electronic component having a first surface on which a connection pad is disposed and a second surface, opposite to the first surface, and an insulating material disposed on the second surface of the electronic component, wherein at least a portion of the component laminate is disposed within the through-portion; and a second insulating layer covering at least a portion of each of the first insulating layer and the component laminate, and disposed in at least a portion of the through-portion. The insulating material includes an organic insulating material.

### CROSS-REFERENCE TO RELATED APPLICATIONS

This application claims benefit of priority to Korean Patent Application No. 10-2024-0058241 filed on May 2, 2024 in the Korean Intellectual Property Office, the disclosure of which is incorporated herein by reference in its entirety.

### BACKGROUND

### 1. Field

The present disclosure relates to a printed circuit board.

### 2. Description of Related Art

Embedding a passive device inside a printed circuit board is required to secure power integrity of server products. However, in the case of server products, it is basically difficult to control warpage due to the large body, so there is a trend to use a thick core layer. In this case, there is a limit to increasing a thickness of the passive device, and thus, there is difficulty in embedding the passive device into the core layer of the substrate due to thickness mismatch. For example, when embedding a passive device which is relatively thinner than the core layer, it may be difficult to fill an empty space with a build-up material.

### SUMMARY

An aspect of the present disclosure is to provide a printed circuit board that can easily embed relatively thin electronic components within a through-portion of a core insulating layer even when a relatively thick core insulating layer is included.

Another aspect of the present disclosure is to provide a printed circuit board which is more advantageous in terms of warpage control and which enables process simplification and cost reductions.

An aspect of the present disclosure is to perform an embedding process, or the like by forming an insulating material on a back surface of an electronic component and matching a thickness of a component laminate embedded therein as similarly as possible to a thickness of a core layer.

According to an example, a printed circuit board may include: a first insulating layer having a through-portion; a component laminate including an electronic component having a first surface on which a connection pad is disposed and a second surface, opposite to the first surface, and an insulating material disposed on the second surface of the electronic component, wherein at least a portion of the component laminate is disposed within the through-portion; and a second insulating layer covering at least a portion of each of the first insulating layer and the component laminate, and disposed in at least a portion of the through-portion. The insulating material may include an organic insulating material.

According to an example, a printed circuit board may include: a core insulating layer having a through-portion; a silicon capacitor disposed in the through-portion, and including a silicon body having a front surface and a back surface and a connection pad disposed on the front surface of the silicon body; an insulating material disposed in the through-portion, and connected to the back surface of the silicon body; and a build-up insulating layer covering at least a portion of each of the core insulating layer, the silicon capacitor, and the insulating material, and disposed in at least a portion of the through-portion. A difference in coefficients of thermal expansion between the silicon body and the insulating material may be smaller than at least one of a difference in coefficients of thermal expansion between the silicon body and the core insulating layer and a difference in coefficients of thermal expansion between the silicon body and the build-up insulating layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a cut plan view taken along line I-I′ of the printed circuit board of FIG. 3;

FIG. 5 is a schematic cross-sectional view of a manufacturing example of the printed circuit board of FIG. 3; and

FIG. 6 is a schematic cross-sectional view of another example of a printed circuit board.

### DETAILED DESCRIPTION

Hereinafter, embodiments of the present disclosure will be described as follows with reference to the attached drawings. The shapes and sizes of elements in the drawings may be exaggerated or reduced for clearer description.

### Electronic Device

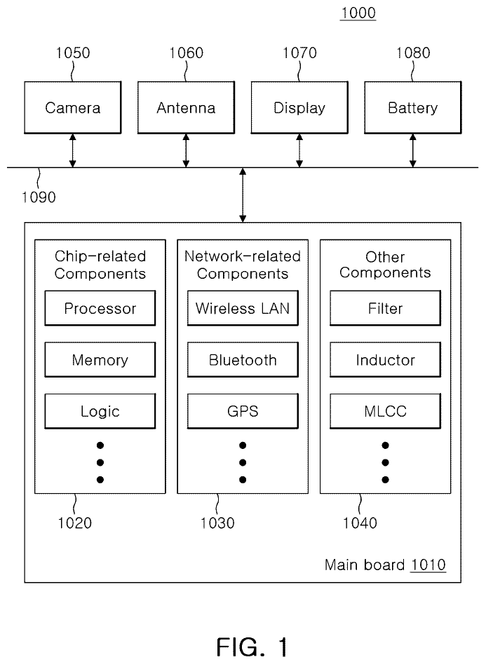

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless

fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. Also, the network related components 1030 may be combined with each other, together with the chip related components 1020 described above.

Other components 1040 may include a high frequency inductor, a ferrite

inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. Also, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. The other components may include, for example, a camera module 1050, an antenna 1060, a display device 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

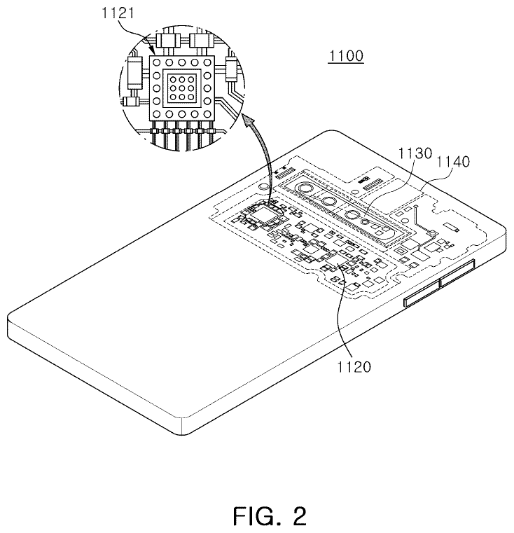

FIG. 2 is a perspective view illustrating an example of an electronic device.

Referring to FIG. 2, the electronic device may be, for example, a smartphone 1100. For example, a motherboard 1110 may be accommodated in the smartphone 1100, and various electronic components 1120 may be physically or electrically connected to the motherboard 1110. Also, other components which may or may not be physically or electrically connected to the motherboard 1110, such as a camera module 1130 and/or a speaker 1140, may be accommodated in the body 1101. A portion of the electronic components 1120 may be the chip related components, a component package 1121, for example, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. The electronic device is not necessarily limited to the smartphone 1100, but may be other electronic devices as described above.

### Printed Circuit Board

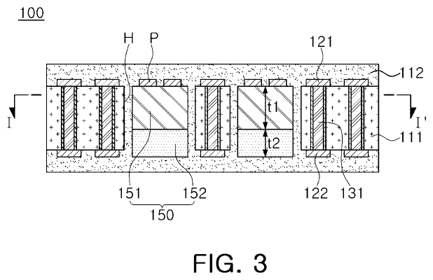

FIG. 3 is a cross-sectional view schematically illustrating an example of a printed circuit board.

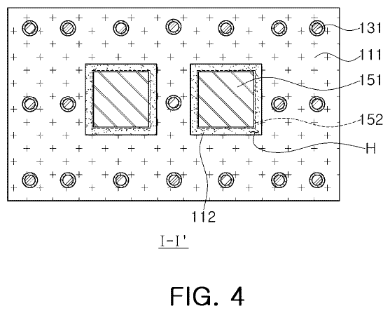

FIG. 4 is a cut plan view taken along line I-I′ of the printed circuit board of FIG. 3.

Referring to FIGS. 3 and 4, a printed circuit board 100 according to an example may include a first insulating layer 111 having a through-portion H, a component laminate 150 including an electronic component 151 having a first surface on which a connection pad P is disposed, and a second surface, opposite to the first surface, and an insulating material 152 disposed on the second surface of the electronic component 151, wherein at least a portion of the component laminate is disposed within the through-portion H, and a second insulating layer 112 covering at least a portion of each of the first insulating layer 111 and the component laminate 150 and filling at least a portion of the through-portion H. Meanwhile, the first and second surfaces of the electronic component 151 may be a front surface and a back surface, respectively. If necessary, first and second wiring layers 121 and 122 respectively disposed on one surface and the other surface of the first insulating layer 111, and a first via layer 131 penetrating the first insulating layer 111 and connecting at least a portion of each of the first and second wiring layers 121 and 122 to each other may be further included. As required, the number of through-portions H and component laminates 150 may respectively be plural, and at least a portion of each of the component laminates 150 may be disposed in each of the through-portions H.

As described above, a printed circuit board 100 according to an example may dispose a component laminate 150 in which an insulating material 152 is disposed on a back surface of the electronic component 151 in the through-portion H of the first insulating layer 111. Accordingly, even when a thickness of the first insulating layer 111 is thick, for example, when the thickness of the first insulating layer 111 is 1.2 mm or more, a thickness of the component laminate 150 may be matched as similarly as possible. Meanwhile, when first and second wiring layers 121 and 122 are formed on the first insulating layer 111, the thickness of the first insulating layer 111 and the component laminate 150 may be matched similarly by considering the thickness of the first and second wiring layers 121 and 122 and the thickness of the connection pad P. Accordingly, a step between the front surface of the electronic component 151 and one surface of the first insulating layer 111 may be minimized. In addition, when filling the through-portion H with the second insulating layer 112, filling may be more easily performed. In addition, the process may be simplified, and as a result, it can have effects such as reducing investment costs, or the like. In addition, even when the first insulating layer 111 is formed of a single layer rather than a plurality of layers, the thickness of the first insulating layer 111 may be increased as desired, such as to a thickness of 1.2 mm or more, and as a result, warpage stability may be further improved. In addition, even when the first insulating layer 111 is formed of a single layer rather than a plurality of layers, the thickness of the first insulating layer 111 may be increased as desired, such as to a thickness of 1.2 mm or more, and as a result, warpage stability may be further improved.

Meanwhile, the electronic component 151 may include a passive device, and more preferably, may include a silicon capacitor (Si capacitor). When the electronic component 151 includes a silicon capacitor, power integrity may be secured more effectively when the printed circuit board 100 is applied to a server product, or the like. Meanwhile, when the electronic component 151 includes a silicon capacitor, for warpage stability, as the insulating material 152, a material having a small difference in coefficients of thermal expansion (CTE) from a body of the silicon capacitor, for example, a silicon body. For example, the difference in coefficients of thermal expansion (CTE) between the silicon body and the insulating material 152 may be smaller than a difference in coefficients of thermal expansion (CTE) between the silicon body and the first insulating layer 111 and/or a difference in coefficients of thermal expansion (CTE) between the silicon body and the second insulating layer 112. Here, the coefficient of thermal expansion (CTE) may be measured by cutting the manufactured printed circuit board 100 to prepare each of the components to be measured as samples of the same size, and using a thermomechanical analysis (TMA) device to perform a tensile test, or the like, under the same conditions.

Meanwhile, the insulating material 152 may include an organic insulating material. For example, the insulating material 152 may include an organic insulating resin, and may further include an inorganic filler and/or an organic filler as needed. For example, the insulating material 152 may include an epoxy molding compound. For example, when the electronic component 151 includes a silicon capacitor, an insulating material 152 may be directly formed on a back surface of the wafer by a back surface molding process in a wafer state, and a thickness of the insulating material 152 may be adjusted by a grinding process, so that a laminate having a desired thickness may be more easily formed by a simpler process. When the cutting process is performed thereafter, the silicon body and the insulating material 152 may be cut together, and thus the insulating material 152 may be disposed only on the back surface of the silicon body, and may not cover a side surface of the silicon body. In one example, a thickness t1 of the silicon body may be greater than a thickness t2 of the insulating material 152. In addition, the side surface of the silicon body and a side surface of the insulating material 152 may substantially be coplanar with each other in cross-section. In one example, a distance from the insulating material 152 to the first insulating layer 111 may be less than the thickness t2 of the insulating material 152.

Hereinafter, components of a printed circuit board 100 according to an example will be described in more detail with reference to the drawings.

Each of the first and second insulating layers 111 and 112 may include an insulating material. The insulating material may include a thermosetting resin such as an epoxy resin, a thermoplastic resin such as polyimide, or a material containing an inorganic filler, an organic filler, and/or a glass fiber (Glass Fiber, Glass Cloth, Glass Fabric), together with these resins. For example, the insulating material may be a non-photosensitive insulating material such as copper clad laminate (CCL), Ajinomoto Build-up Film (ABF), prepreg (PPG), or the like, but the present disclosure is not limited thereto, and other polymer materials may be used as the insulating material. In addition, the insulating material may be a photosensitive insulating material such as a Photoimageable Dielectric (PID). As a non-limiting example, the first insulating layer 111 may include CCL, and the second insulating layer 112 may include ABF or PPG.

The first insulating layer 111 may be a core insulating layer. The second insulating layer 112 may be a build-up insulating layer. The first insulating layer 111 may be a single layer. The second insulating layer 112 may include a plurality of layers. At least a portion of the second insulating layer 112 may be disposed on one surface of each of the first insulating layer 111 and the component laminate 150 to cover at least a portion of the first wiring layer 121. At least another portion of the second insulating layer 112 may be disposed on the other surface of each of the first insulating layer 111 and the component laminate 150 to cover at least a portion of the second wiring layer 122. The first insulating layer 111 may have a higher rigidity than the second insulating layer 112. For example, the first insulating layer 111 may have a higher elastic modulus than the second insulating layer 112. The first insulating layer 111 may be thicker than the second insulating layer 112. In this case, the thickness of the second insulating layer 112 may be a thickness between the upper and lower surfaces of the second insulating layer, excluding the thickness of the first insulating layer 111 disposed therebetween.

The through-portion H may penetrate between one surface and the other surface of the first insulating layer 111. For example, the through-portion H may be in the form of a through cavity. However, the present disclosure is not limited thereto, and if necessary, the through-portion H may be in the form of a blind cavity penetrating only a portion of the first insulating layer 111 from one surface or the other surface of the first insulating layer 111.

Each of the first and second wiring layers 121 and 122 may include a metal material. Each of the first and second wiring layers 121 and 122 may include a metal material. The metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure not limited thereto. Each of the first and second wiring layers 121 and 122 may perform various functions depending on a design thereof. For example, each of the first and second wiring layers 121 and 122 may include a signal pattern, a power pattern, a ground pattern, and the like. Each of the above-described patterns may have various forms such as a line, a plane, a pad, and the like. Each of the first and second wiring layers 121 and 122 may include an electroless plating layer (or chemical copper) and an electrolytic plating layer (or electrolytic copper). Alternatively, the first and second wiring layers 121 and 122 may include a metal foil (or copper foil) and an electrolytic plating layer (or electrolytic copper). Alternatively, the first and second wiring layers 121 and 122 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

The first via layer 131 may include a metal material. The metal material may include copper (Cu), aluminum (Al), silver (Ag), tin (Sn), gold (Au), nickel (Ni), lead (Pb), titanium (Ti), and/or alloys thereof. The metal material may preferably include copper (Cu), but the present disclosure is not limited thereto. The first via layer 131 may include a through via. The through via may include a Plated Though Hole (PTH) in which the metal material described above is conformally formed on a wall surface of the through hole penetrating the first insulating layer 111 by plating and an insulating material is filled therein. The through via of the first via layer 131 may perform various functions depending on a design thereof. For example, the through-via may include ground vias, power vias, signal vias, and the like. The first via layer 131 may include an electroless plating layer (or chemical copper) and an electrolytic plating layer (or electrolytic copper), but the present disclosure is not limited thereto. A sputtering layer may be included instead of the electroless plating layer (or chemical copper), and both may be included.

An electronic component 151 may be disposed in the through-portion H of the first insulating layer 111. The electronic component 151 may include a body with an integrated circuit formed therein. The body may be formed based on an active wafer, and in this case, silicon (Si), or the like, may be used as a base material for each body. A connection pad P may include a conductive material such as aluminum (Al) or copper (Cu). A surface on which the connection pad P is disposed may be a front surface or an active surface, and an opposite surface thereof may be a back surface or an inactive surface. The electronic component 151 may include a silicon capacitor, but the present disclosure is not limited thereto.

The insulating material 152 may be disposed on the back surface of the electronic component 151 in the through-portion H of the first insulating layer 111. For example, the insulating material 152 may be directly connected to the back surface of the electronic component 151. The insulating material 152 may include an organic insulating material. The organic insulating material may include a thermosetting resin such as an epoxy resin, a thermoplastic resin such as polyimide, or a material including an inorganic filler and/or an organic filler together with these resins. For example, the insulating material 152 may include, but the present disclosure is not limited thereto, an Epoxy

Molding Compound (EMC), or the like.

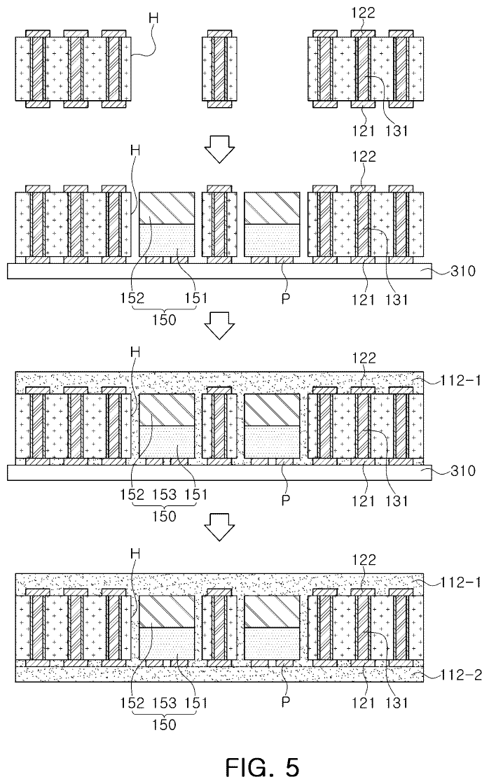

FIG. 5 is a cross-sectional view schematically illustrating a manufacturing example of the printed circuit board of FIG. 3.

First, referring to FIG. 5, a first insulating layer 111 may be prepared using CCL, or the like, and a through-portion H, first and second wiring layers 121 and 122, and a first via layer 131 may be formed in the first insulating layer 111. The through-portion H may be formed using mechanical drilling, laser drilling, blast processing, or the like. The via hole for the first via layer 131 may also be formed using a mechanical drilling, laser drilling, or the like. The first and second wiring layers 121 and 122 and the first via layer 131 may be formed using a circuit formation process such as Additive Process (AP), Semi AP (SAP), Modified SAP (MSAP), Tenting (TT), or the like. When forming the first via layer 131, a plugging process may be included to fill the interior of the through via with an insulating material.

Next, referring to FIG. 5, a tape 310 is attached to a lower side of the first insulating layer 111. The tape 310 may be attached to the first wiring layer 121. The tape 310 may block a lower portion of the through-portion H. Thereafter, a component laminate 150 in which an insulating material 152 is formed on a back surface of the electronic component 151 to match the thickness of the first insulating layer 111 may be disposed in the through-portion H. for example, the component laminate 150 may be disposed so that a front surface on which the connection pad P of the electronic component 151 is disposed is attached to the tape 310.

Next, referring to FIG. 5, a 2-1 insulating layer 112-1 covering at least a portion of each of the first insulating layer 111 and the first and second wiring layers 121 and 122 and the component laminate 150 and filling at least a portion of the through-portion H may be formed on the tape 310. The 2-1 insulating layer 112-1 may be formed by a lamination process while attached to a film such as PolyEthylene Terephthalate (PET), or the like.

Next, referring to FIG. 5, the tape 310 may be removed, and a 2-2 insulating layer 112-2 may be formed on a region from which the tape 310 was removed, for example, on a 2-1 insulating layer 112-1. The 2-2 insulating layer 112-2 may also be formed by a lamination process while attached to a film such as PET, or the like. The 2-1 and 2-2 insulating layers 112-1 and 112-2 may be integrated to the extent that the boundaries therebetween are indistinguishable after curing, but the present disclosure is not limited thereto.

The printed circuit board 100 according to the above-described example may be manufactured through a series of processes, and any other redundant descriptions thereof are omitted. Meanwhile, in a series of processes, it was explained that the process is performed in an upside-down manner as compared to the printed circuit board 100 according to the above-described example, and it is obvious that the printed circuit board 100 according to the above-described example may be manufactured through upside-down inversion after the process is completed.

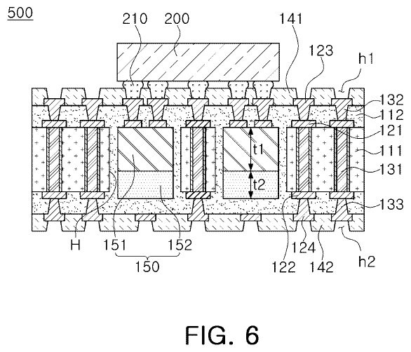

FIG. 6 is a cross-sectional view schematically illustrating another example of a printed circuit board.

Referring to FIG. 6, in the printed circuit board according to the above-described example, a printed circuit board 500 according to another example may include third and fourth wiring layers 123 and 124 respectively disposed on one surface and the other surface of the second insulating layer 112, a second via layer 132 penetrating a portion of one side of the second insulating layer 112 and connecting at least a portion of each of the first and third wiring layers 121 and 123 and at least a portion of each of the first wiring layer 121 and the connection pad P to each other, a third via layer 133 penetrating a portion of the other side of the second insulating layer 112 and connecting at least a portion of each of the second and fourth wiring layers 122 and 124 to each other, a first resist layer 141 disposed on one surface of the second insulating layer 112 and having a plurality of first openings (h1) respectively exposing at least a portion of the third wiring layers 123 and 124, a second resist layer 142 disposed on the other surface of the second insulating layer 112 and having a plurality of second openings (h2) respectively exposing at least a portion of the fourth wiring layer 124, and a semiconductor chip 200 disposed on one surface of the first resist layer 141 and connected to at least a portion of the exposed third wiring layer 123 though a connection member 210. For example, the printed circuit board 500 according to another example may include a printed circuit board 100 according to the above-described example as a package substrate having a component laminate 150 embedded therein, and may have a form of a semiconductor package in which a semiconductor chip 200 is mounted on the package substrate.

Hereinafter, components of a printed circuit board 500 according to another example will be described in more detail with reference to the drawings.

Each of the third and fourth wiring layers 123 and 124 may include a metal material. The metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure not limited thereto. Each of the third and fourth wiring layers 123 and 124 may perform various functions depending on a design thereof. For example, each of the third and fourth wiring layers 123 and 124 may include a signal pattern, a power pattern, a ground pattern, and the like. Each of the above-described patterns may have various forms such as a line, a plane, a pad, and the like. Each of the third and fourth wiring layers 123 and 124 may include an electroless plating layer (or chemical copper) and an electrolytic plating layer (or electrolytic copper). Alternatively, the third and fourth wiring layers 123 and 124 may include a metal foil (or copper foil) and an electrolytic plating layer (or electrolytic copper). Alternatively, the third and fourth wiring layers 123 and 124 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

Each of the second and third via layers 132 and 133 may include a metal material. The metal material may include copper (Cu), aluminum (Al), silver (Ag), tin (Sn), gold (Au), nickel (Ni), lead (Pb), titanium (Ti), and/or alloys thereof. The metal material may preferably include copper (Cu), but the present disclosure is not limited thereto. Each of the second and third via layers 132 and 133 may include a micro via. The micro via may be a filled via filling a via hole or a conformal via disposed along a wall surface of the via hole. The micro via may be disposed in a stacked type and/or a staggered type. The micro via of each of the second and third via layers 132 and 133 may perform various functions depending on a design thereof. For example, the micro via may include ground vias, power vias, signal vias, and the like. Each of the second and third via layers 132 and 133 may include an electrodeless plating layer (or chemical copper) and an electrolytic plating layer (or electrolytic copper), but the present disclosure is not limited thereto. A sputtering layer may be formed instead of an electroless plating layer, or both thereof may be included. The second and third via layers 132 and 133 may have may have tapered shapes in opposite directions.

Each of the first and second resist layers 141 and 142 may include a liquid or film-type solder resist, but the present disclosure is not limited thereto, and may also include other types of insulating materials such as ABF, or the like. Each of the first and second resist layers 141 and 142 may have a plurality of first and second openings h1 and h2 exposing at least a portion of each of the third and fourth wiring layers 123 and 124. A surface treatment layer may be formed on a pattern exposed by the plurality of first and/or second openings h1 and h2 as needed.

The semiconductor chip 200 may include an integrated circuit (IC) die in

which hundreds to millions of circuits or more are integrated into a single chip. In this case, the integrated circuit may include, for example, an application processor (e.g., AP) such as a central processor (e.g., CPU), a graphics processor (e.g., GPU), a field programmable gate array (FPGA), a digital signal processor, a cryptographic processor, a microprocessor, or a microcontroller, a logic chip such as an analog-to-digital converter, or an application-specific integrated circuit (ASIC), but the present disclosure is not limited thereto, and the integrated circuit may be a memory chip such as a volatile memory (e.g., a dynamic random access memory (DRAM)), a non-volatile memory (e.g., a read only memory (ROM)), a flash memory, a high bandwidth memory (HBM), or the like, or may be other types such as a power management IC (PMIC).

The semiconductor chip 200 may be formed based on an active wafer, and in this case, silicon (Si), germanium (Ge), gallium arsenide (GaAs), or the like may be used as a base material comprising each body. Various circuits may be formed on the body. A connection pad may be formed on each body, and the connection pad may include a conductive material such as aluminum (Al) or copper (Cu). The semiconductor chip 200 may be a bare die, and in this case, metal bumps may be disposed on the connection pad. The semiconductor chip 200 may be a packaged die. In this case, a redistribution layer may be additionally formed on the connection pad, and metal bumps may be disposed on the redistribution layer.

A connection member 210 may be formed of a low-melting point metal, for example, solder such as tin (Sn)-aluminum (Al)-copper (Cu), but this is merely an example and a material thereof is not particularly limited thereto. The connection member 210 may be formed of a plurality of layers or a single layer. When formed of multiple layers, the connection member 210 may include a copper pillar and solder. When formed of a single layer, the connection member 210 may include tin-silver solder or copper, but the present disclosure is not limited thereto.

Other details are substantially the same as those described in the printed circuit board 100 according to the above-described example, and thus, redundant descriptions are omitted.

In the example embodiments, the term “covering” may include not only covering completely but also covering at least partially, and may also include covering indirectly as well as covering directly. Further, it may also include not only covering directly but also covering indirectly. In addition, the term “filling” may include filling roughly as well as filling completely, and may include a case in which, fore example, some gaps or voids exist.

In the example embodiments, the meaning on a cross-section may mean a cross-sectional shape when an object is vertically cut, or a cross-sectional shape when the object is viewed from the side. Also, the meaning on a plane may refer to a planar shape when the object is horizontally cut, or a planar shape when the object is viewed from the top or the bottom.

In the example embodiments, a thickness, a width, a length, a depth, and the like, may be measured using a scanning microscope, an optical microscope, or the like, based on a cross-section a printed circuit board that has been polished or cut, respectively. The cut cross-section may be a vertical cross-section or a horizontal cross-section, and each value may be measured based on a required cut cross-section. In this case, when the value is not constant, the value may be determined as an average value of values measured at five arbitrary points.

In the example embodiments, the terms “a lower side, a lower portion, a lower surface, the other surface”, and the like, are used to refer to a downward direction based on the cross-section of the drawing for convenience, and the terms “an upper side, an upper portion, an upper surface, one surface”, and the like, are used as the opposite directions. In addition, the terms “a side portion, a side surface”, and the like, are used to refer to a direction perpendicular to the upper and lower surfaces. However, the direction is defined as above for ease of description, and the scope of the claims is not limited to any particular example by the descriptions of the directions.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as being relevant to the other example embodiment unless otherwise indicated.

The terms used herein describe particular embodiments only, and the present disclosure is not limited thereby. As used herein, the singular forms “a,” “an,” and “the” are intended to include the plural forms as well, unless the context clearly indicates otherwise.

As set forth above, as one of the many effects of the present disclosure, a printed circuit board that can easily embed relatively thin electronic components within a through-portion even when a relatively thick core insulating layer is included, may be provided.

As another effect of the present disclosure, a printed circuit board which is more advantageous in terms of warpage control and which enables process simplification and cost reduction, may be provided.

While the example embodiments have been illustrated and described above, it will be apparent to a person skilled in the art that modifications and variations could be made without departing from the scope of the present disclosure as defined by the appended claims.

What is claimed is:

1. A printed circuit board, comprising:
a first insulating layer having a through-portion;
a component laminate including an electronic component having a first surface on which a connection pad is disposed and a second surface, opposite to the first surface, and an insulating material disposed on the second surface of the electronic component, wherein at least a portion of the component laminate is disposed within the through-portion; and
a second insulating layer covering at least a portion of each of the first insulating layer and the component laminate, and disposed in at least a portion of the through-portion, wherein the insulating material includes an organic insulating material.

2. The printed circuit board of claim 1, wherein the electronic component includes a silicon capacitor (Si Capacitor).

3. The printed circuit board of claim 1, wherein the insulating material includes an epoxy molding compound.

4. The printed circuit board of claim 1, wherein the insulating material is directly connected to the second surface of the electronic component.

5. The printed circuit board of claim 1, wherein the insulating material is disposed only on the second surface of the electronic component among surfaces of the electronic component.

6. The printed circuit board of claim 1, wherein the first insulating layer is a single layer having a thickness of 1.2 mm or more.

7. The printed circuit board of claim 1, further comprising:
first and second wiring layers respectively disposed on one surface and the other surface of the first insulating layer; and
a first via layer penetrating the first insulating layer, and connecting at least a portion of each of the first and second wiring layers to each other.

8. The printed circuit board of claim 7, wherein at least a portion of the second insulating layer is disposed on one surface of each of the first insulating layer and the component laminate, to cover at least a portion of the first wiring layer, and
at least another portion of the second insulating layer is disposed on the other surface of each of the first insulating layer and the component laminate, to cover at least a portion of the second wiring layer.

9. The printed circuit board of claim 8, further comprising:
third and fourth wiring layers respectively disposed on one surface and the other surface of the second insulating layer;
a second via layer penetrating a portion of one side of the second insulating layer, and connecting at least a portion of each of the first and third wiring layers and at least a portion of each of the first wiring layer and the connection pad to each other; and
a third via layer penetrating a portion of the other side of the second insulating layer, and connecting at least a portion of each of the second and fourth wiring layers to each other.

10. The printed circuit board of claim 9, further comprising:
a first resist layer disposed on one surface of the second insulating layer, and having a plurality of first openings respectively exposing at least a portion of the third wiring layer; and
a second resist layer disposed on the other surface of the second insulating layer, and having a plurality of second openings respectively exposing at least a portion of the fourth wiring layer.

11. The printed circuit board of claim 10, further comprising:
a semiconductor chip disposed on one surface of the first resist layer, and connected to at least a portion of the exposed third wiring layer.

12. The printed circuit board of claim 1, wherein the through-portion and the plurality of component laminate are provided in plural forms, respectively, and
at least a portion of each of the component laminates is disposed in each of the through-portions.

13. The printed circuit board of claim 1, wherein the insulating material is a material different from a material of the second insulating layer.

14. The printed circuit board of claim 1, wherein a distance from the insulating material to the first insulating layer is less than a thickness of the insulating material.

15. The printed circuit board of claim 1, wherein the insulating material includes one surface facing the electronic component and another surface opposing the one surface, the another surface of the insulating material being in contact with the second insulating layer.

16. A printed circuit board, comprising:
a core insulating layer having a through-portion;
a silicon capacitor disposed in the through-portion, and including a silicon body having a front surface and a back surface and a connection pad disposed on the front surface of the silicon body;
an insulating material disposed in the through-portion, and connected to the back surface of the silicon body; and
a build-up insulating layer covering at least a portion of each of the core insulating layer, the silicon capacitor, and the insulating material, and disposed in at least a portion of the through-portion,
wherein a difference in coefficients of thermal expansion between the silicon body and the insulating material is smaller than at least one of a difference in coefficients of thermal expansion between the silicon body and the core insulating layer and a difference in coefficients of thermal expansion between the silicon body and the build-up insulating layer.

17. The printed circuit board of claim 16, wherein a thickness of the silicon body is thicker than a thickness of the insulating material.

18. The printed circuit board of claim 16, wherein a side surface of the silicon body and a side surface of the insulating material are substantially coplanar with each other in a cross-section.
